(19) United States
(12) Patent Application Publication
(10) Pub. No.: US 2013/0155587 A1
(43) Pub. Date: Jun. 20, 2013

(54) FLAT-PANEL DISPLAY DEVICE

(71) Applicant: SANYO Electric Co., Ltd., Osaka (JP)

(72) Inventors: Nobuyuki Take, Higashiosaka-shi (JP); Tsuyoshi Okumura, Higashiosaka-shi (JP)

(73) Assignee: SANYO ELECTRIC CO., LTD., Osaka (JP)

(21) Appl. No.: 13/714,941

(22) Filed: Dec. 14, 2012

(30) Foreign Application Priority Data
Dec. 20, 2011 (JP) 2011-277954

(51) Int. Cl. H05K 5/00

(52) U.S. Cl. CPC H05K 5/0017
USPC 361/679.01

(57) ABSTRACT

A flat-panel display device according to the present invention includes a device main body 20 including a display 11 surrounded with cabinets 21, 23 having a mounting hole 25 formed forward from a back face to intersect, at right angles, with a plane P including a vertical line passing through a gravity center G of the device main body and to extend at least to the plane, and a stand 30 including a support pillar portion 32 mounted to the cabinet from a back face side thereof and a base portion 31 configured to retain the support pillar portion in a setting up state, the stand enabling the device main body to stand alone when the support pillar portion is mounted to the device main body by a shaft portion 40 that is engaged in the mounting hole to reach the plane.

### CROSS-REFERENCE TO RELATED APPLICATIONS

Japanese Patent Application No. 2011-277954 filed on Dec. 20, 2011 from which the present application claims priority is hereby incorporated by reference.

### FIELD OF THE INVENTION

The present invention relates to a flat-panel display device including a liquid crystal display, and particularly to a flat-panel display device capable of mounting a stand for enabling a device main body to stand alone.

### DESCRIPTION OF RELATED ART

A flat-panel display device of thin type including a liquid crystal display is configured by surrounding the liquid crystal display with a cabinet so that the liquid crystal display is viewable from the front. Because a device main body of the flat-panel display device is thin, it is necessary to mount a stand to the cabinet to enable the device main body to stand alone on a table or a floor face. In general, the stand has a base portion and a support pillar portion, and the support pillar portion is mounted to the cabinet from a back face side thereof.

Because the liquid crystal display is disposed on a front side of the cabinet, a gravity center of the device main body is positioned on a front side of the device main body apart from a center thereof.

Therefore, when the stand is mounted to the device main body from the back face side, the device main body tilts forward due to a moment to fall the device main body forward.

In particular, when the cabinet and the stand are made of resin, they are deformed due to temperature change, deterioration over time and the like, with the result that the forward tilting becomes pronounced.

Therefore, it is proposed to mount the support pillar portion of the stand to the cabinet from the back face thereof, along with provide near a lower end of the support pillar portion a receiving face with which a bottom surface of the device main body comes in contact in order to apply a gravity center of the device main body on the receiving face, thereby enabling the flat-panel display device to stand alone.

However, the method in which a lower end of the device main body is brought into contact with the receiving face of the stand restricts product design of the flat-panel display device. Moreover, when there are product variations in the cabinet and the stand or when the stand is mounted improperly, the receiving face may not be able to support the device main body properly.

### SUMMARY OF THE INVENTION

It is an object of the present invention to provide a flat-panel display device of thin type, a device main body of which can be supported more stably and prevented from falling.

A flat-panel display device according to the present invention includes

a device main body including a display surrounded with a cabinet having a mounting hole formed forward from a back face to intersect, at right angles, with a plane including a vertical line passing through a gravity center of the device main body and to extend at least to the plane and

a stand including a support pillar portion mounted to the cabinet from a back face side thereof and a base portion configured to retain the support pillar portion in a setting up state, the stand enabling the device main body to stand alone when the support pillar portion is mounted to the device main body by a shaft portion that is engaged in the mounting hole to reach the plane.

### BRIEF DESCRIPTION OF THE DRAWINGS

FIG. 1 is a perspective view seen from a back face side of a flat-panel display device of an embodiment of the present invention;

FIG. 2 is an exploded perspective view of the flat-panel display device with stands detached;

FIG. 3 is a sectional view along line A-A seen in a direction of arrows of the line in FIG. 1; and

FIG. 4 is an enlarged sectional view of a portion surrounded by a circle B in FIG. 3.

### DETAILED DESCRIPTION OF THE PREFERRED EMBODIMENT

An embodiment of a flat-panel display device 10 of thin type according to the present invention will be specifically described below with reference to the drawings.

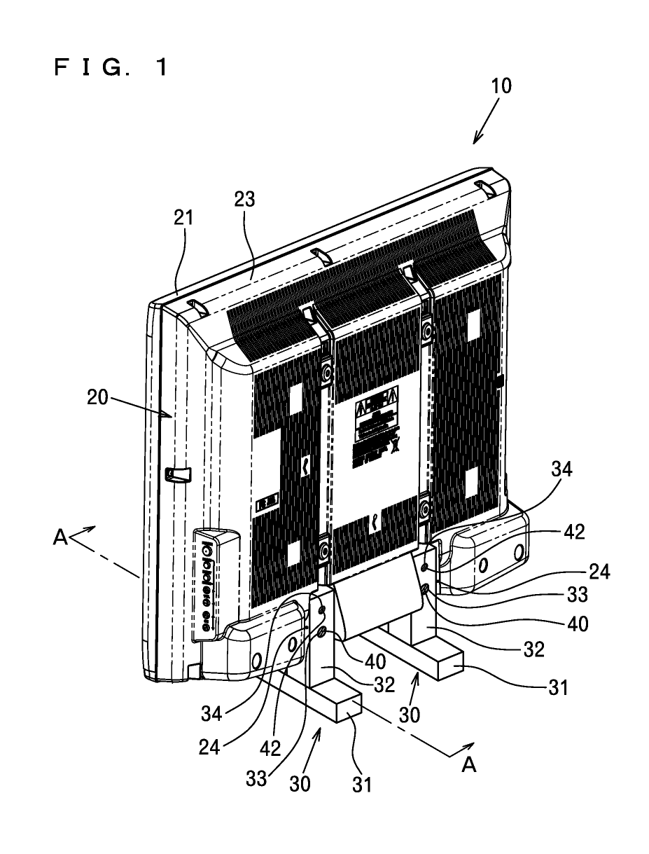

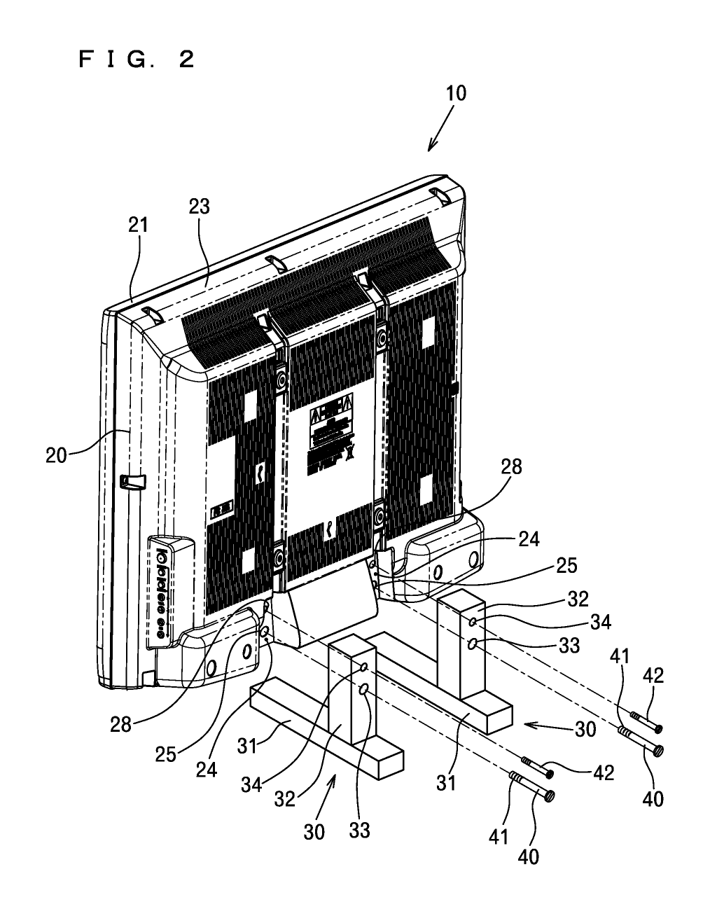

The flat-panel display device 10 of the embodiment of the present invention is configured by a device main body 20 and stands 30 as shown in FIGS. 1 and 2, in which the stands 30 are mounted by shaft portions 40 to the device main body 20 from a back face side thereof, thereby enabling the flat-panel display device 10 to stand alone on a table or a floor face.

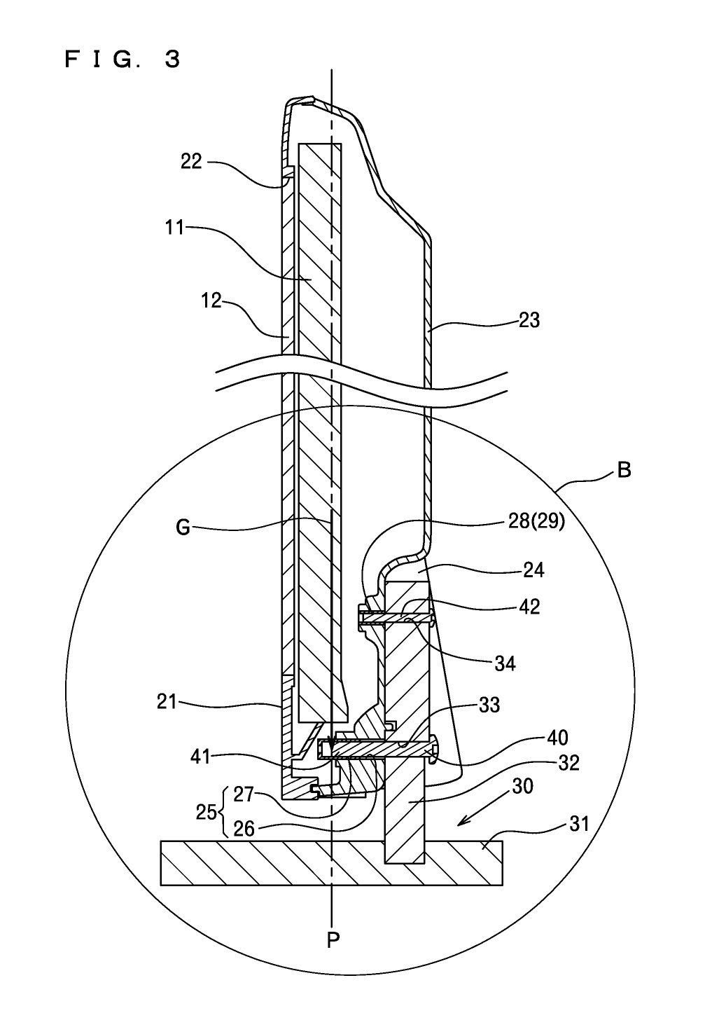

An outer periphery of the device main body 20 is covered with a cabinet configured by a front cabinet 21 and a back cabinet 23, and a liquid crystal display 11 for displaying images and the like is disposed inside the cabinets 21, 23 as shown in FIG. 3. The front cabinet 21 and the back cabinet 23 are integrated with each other by screwing or the like.

The liquid crystal display 11 housed in the cabinets 21, 23 can be a unit including a panel plane for displaying the images, a backlight and the like, and electronic parts (not shown) such as a microcomputer for controlling the device main body 20 and a power supply unit are mounted to a back face side of the liquid crystal display 11.

As shown in FIGS. 1 to 4, each of the stands 30 includes a base portion 31 extending in a front-back direction and a support pillar portion 32 setting up from the base portion 31. The support pillar portion 32 sets up from a position closer to a back side of the base portion 31 apart from a center thereof.

Although the device main body 20 is supported by a pair of left and right stands 30, 30 in the embodiment as shown in the drawings, the two support pillar portions 32, 32 may set up from a wide base portion 31. Alternatively, only one support pillar portion 32 may set up from a center of the wide base portion 31.

The base portion 31 and the support pillar portion 32 may be made of metal. The base portion 31 and the support pillar portion 32 may be made by aluminum extrusion in order to save the weight. The base portion 31 and the support pillar portion 32 can be connected to each other by screwing, welding, bonding, or the like.

When the base portion 31 and/or the support pillar portion 32 are made by aluminum extrusion, it is preferable to make them hollow bodies having a reinforcing rib thereinside in order to save the weight and secure the strength.

It is of course possible to make the base portion 31 and the support pillar portion 32 by using other metal than aluminum, or by using resin, and the base portion 31 may be made of different material from that of the support pillar portion 32.

A shaft hole 33 is formed through the support pillar portion 32 in the front-back direction, through the shaft hole 33 a shaft portion 40 for mounting the stand 30 to the back cabinet 23 being inserted. An auxiliary shaft hole 34 for screwing is formed through the support pillar portion 32 in the front-back direction above the shaft hole 33.

In the embodiment as shown in the drawings, the shaft hole 33 is formed to have a larger diameter than that of the auxiliary shaft hole 34.

A rectangular window frame 22 is formed in the front cabinet 21 of the device main body 20 and thus the liquid crystal display 11 is viewable through a glass plate 12 fitted in the window frame 22. The liquid crystal display 11 is disposed on a front side in the cabinets 21, 23 to be close to the glass plate 12.

As shown in FIGS. 1 to 4, in a bottom portion of the back face of the back cabinet 23 are formed recessed portions 24, 24 opening toward the backside and the downside, into which the support pillar portions 32 of the stands 30 (described later) can be fitted and fixed, respectively. In the embodiment as shown in the drawings, the left and right recessed portions 24, 24 are paired.

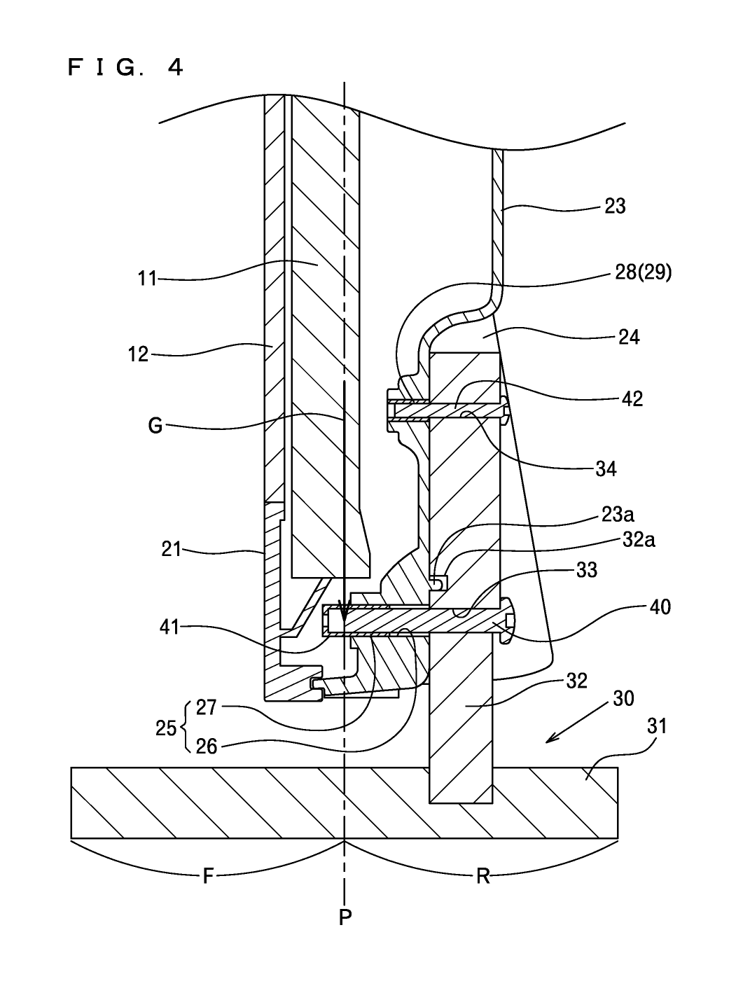

As shown in FIGS. 2 to 4, in the recessed portions 24, 24 are formed mounting holes 25, 25 forward from the back faces for mounting the support pillar portions 32 of the stands 30, respectively. As shown in an enlarged view in FIG. 4, the mounting holes 25, 25 are formed by increasing wall thickness of the back cabinet 23, forming through holes 26 through the back cabinet 23, and fitting into the through holes 26 metal female threaded cylinders 27 that are internally threaded.

The mounting holes 25, 25 are formed substantially perpendicularly forward from the back face of the liquid crystal display 11 to intersect, at right angles, with a plane P including a vertical line of a gravity center G of the device main body 20 as shown in FIGS. 3 and 4. Because the gravity center G of the device main body 20 is positioned on a front side apart from a center due to the heavy liquid crystal display 11 and glass plate 12, the mounting holes 25, 25 are formed to have such depths as to extend from the center of the device main body 20 to the front side thereof so as to at least intersect with the plane P.

In the embodiment as shown in the drawings, auxiliary mounting holes 28, 28 are respectively formed at positions above the mounting holes 25, 25 so as to face the auxiliary shaft holes 34 of the support pillar portions 32. As shown in FIG. 4, the auxiliary mounting holes 28, 28 are formed to be shallower than the mounting holes 25, 25, and female threaded cylinders 29 are similarly fitted in the auxiliary mounting holes 28, 28. In more detail, the auxiliary mounting holes 28 have such lengths as not to reach the above-described plane P including the vertical line of the gravity center G of the device main body 20. This is because of the below reasons. The auxiliary mounting holes 28 are for auxiliary roles. Moreover, if the auxiliary mounting holes 28 are formed to be deep, they intersect with electronic parts such as the liquid crystal display 11. To avoid this, it is necessary to increase the depth of the device main body 20, however, this increases the device main body 20 in size.

The auxiliary mounting holes 28, 28 of the device main body 20 may be formed to have smaller diameters than the mounting holes 25, 25.

The mounting holes 25 of the device main body 20 are connected to the stands 30 by the shaft portions 40 as shown in FIGS. 2 to 4.

The device main body 20 are connected to the stands 30, 30 by the shaft portions 40 as shown in FIGS. 2 to 4 such that the support pillar portions 32, 32 are inserted into the recessed portions 24, 24 from the back face side of the device main body 20 with the mounting holes 25, 25 aligned with the shaft holes 33, 33.

In order to facilitate the alignment of the mounting holes 25, 25 with the shaft holes 33, 33, as shown in FIG. 4, a positioning projection 23a may be formed on the back cabinet 23, and a positioning hole 32a may be formed in the support pillar portion 32 to be engaged with the positioning projection 23a.

An example of each of the shaft portions 40, 40 is a metal bolt, on a tip end of which a male thread 41 is formed, as shown in FIGS. 2 and 3 and more specifically in FIG. 4. The shaft portion 40 enters the shaft hole 33 and the male thread 41 at its tip end is screwed into the female threaded cylinder 27 in the mounting hole 25, thereby connecting the device main body 20 to the stand 30.

Each of the shaft portions 40 has at least such a length as to reach the plane P including the gravity center G of the device main body 20. The shaft portions 40 intersect, at right angles, with the plane P when fastened. As a result, the weight of the device main body 20 acts perpendicularly on the shaft portions 40.

In the embodiment, as shown in the drawings, in addition to the combination of the mounting holes 25 and the shaft holes 33, the auxiliary mounting holes 28 and the auxiliary shaft holes 34 are formed, which are fastened to each other similarly to the above-described manner. An example of a member inserted into the auxiliary mounting hole 28 and the auxiliary shaft hole 34 is a bolt-like auxiliary shaft portion 42 which enters the auxiliary shaft hole 34 and is screwed into the female threaded cylinder 29 of the auxiliary mounting hole 28.

Because the auxiliary mounting hole 28 and the auxiliary shaft hole 34 are formed to be shallower and have smaller diameters than the mounting hole 25 and the shaft hole 33, the auxiliary shaft portion 42 is used which is shorter and has a smaller diameter than the shaft portion 40. In this way, it is possible to prevent from making a mistake in mounting the shaft portion 40 or the auxiliary shaft portion 42.

The connection of the device main body 20 to the stands 30 by the auxiliary shaft portions 42 can reinforce the connection by the shaft portions 40, with the result that the device main body 20 can be mounted more stably to the stands 30.

By mounting the stands 30 to the device main body 20 as described above, it is possible to place the device main body 20 on the table or the floor face.

According to the present invention, the shaft portions 40 have such lengths as to intersect, at right angles, with the plane P including the vertical line of the gravity center G of the device main body 20 and thus the weight of the device main body 20 acts perpendicularly on the shaft portions 40. Therefore, the moment to fall the device main body 20 forward is not generated, making it possible to prevent forward-tilting and falling of the device main body.

When the shaft portions 40 on which the weight of the device main body 20 acts perpendicularly are metal bolts, and the portions of the cabinet 23 to be engaged with the shaft portions 40 are provided with the metal female threaded cylinders 27, their deformations due to temperature change and deterioration over time can be suppressed, making it possible to maintain the strong and stable support over a long time period.

The weight of the device main body 20 applied on each of the shaft portions 40 acts from the shaft portion 40 through the support pillar portion 32 on the base portion 31. When the support pillar portions 32 and the base portions 31 are made of metal, their deformation due to temperature change and deterioration over time can be suppressed similarly, making it possible to maintain the strong and stable support over a long time period.

As shown in FIG. 4, it is preferable to mount the support pillar portion 32 to the base portion 31 such that a front-side distance F and rear-side distance R of the base portion 31 from the plane P including the vertical line of the gravity center G of the device main body 20 are substantially the same as each other. In this way, it is possible to more stably support the device main body 20.

According to the present invention, it is possible to miniaturize the stands 30 to reduce a space for placing the flat-panel display device 10 and reduce a packing space in shipping or the like as well.

The structures of the respective portions of the present invention are not restricted to those in the above-described embodiment and can be changed in various ways in a technical scope described in the claims. The present invention can be carried out not only in a liquid crystal television receiver but also in various flat-panel display devices.

What is claimed is:

1. A flat-panel display device comprising:
a device main body including a display surrounded with a cabinet having a mounting hole formed forward from a back face to intersect, at right angles, with a plane including a vertical line passing through a gravity center of the device main body and to extend at least to the plane; and
a stand including a support pillar portion mounted to the cabinet from a back face side thereof and a base portion configured to retain the support pillar portion in a setting up state, the stand enabling the device main body to stand alone when the support pillar portion is mounted to the device main body by a shaft portion that is engaged in the mounting hole to reach the plane.

2. The flat-panel display device according to claim 1, wherein at least a portion of the mounting hole intersecting with the plane at right angles is made of metal.

3. The flat-panel display device according to claim 1, wherein at least the support pillar portion of the stand is made of metal.

4. The flat-panel display device according to claim 3, wherein the support pillar portion is an aluminum hollow extruded product.
